(19) United States
(12) Patent Application Publication
(10) Pub. No.: US 2020/0259309 A1
(43) Pub. Date: Aug. 13, 2020

(54) LIGHT-EMITTING SEMICONDUCTOR COMPONENT

(71) Applicant: OSRAM OLED GMBH, Regensburg (DE)

(72) Inventors: Alfred LELL, Maxhütte-Haidh (DE); Muhammad ALI, Regensburg (DE); Bernhard STOJETZ, Wiesent (DE); Harald KÖNIG, Bernhardswald (DE)

(21) Appl. No.: 16/647,324

(22) PCT Filed: Sep. 12, 2018
(86) PCT No.: PCT/EP2018/074586

§ 371 Date: Mar. 13, 2020

(30) Foreign Application Priority Data
Sep. 15, 2017 (DE) 10 2017 121 480.1

(51) Int. Cl. H01S 5/024; H01S 5/40; H01S 5/30; H01S 5/00

(52) U.S. Cl. CPC H01S 5/02476; H01S 5/4012; H01S 5/005; H01S 5/4031; H01S 5/3013

(57) ABSTRACT

A light-emitting semiconductor component (99) comprising a laser bar (100) comprising at least two individual emitters (2), and a conversion element (300) arranged downstream of the laser bar (100) in the beam path, wherein at least some of the individual emitters (2) are arranged side by side in a lateral transverse direction (X), the laser bar (100) is formed with a nitride compound semiconductor material, the individual emitters (2) are configured to emit primary radiation (L1) during normal operation and the conversion element (300) is configured to convert at least part of the primary radiation (L1) into secondary radiation (L2), the secondary radiation (L2) having a longer wavelength than the primary radiation (L1).

A light-emitting semiconductor component is specified. One of the tasks to be solved is to specify a light-emitting semiconductor component which has an improved efficiency and can be manufactured at a particularly low cost.

The light-emitting semiconductor component is, for example, a part of a lighting device which is intended for general lighting or as a light source in a headlamp. Furthermore, the light-emitting semiconductor component may be intended, for example, as a light source in a projection device.

According to at least one embodiment, the light-emitting semiconductor component comprises a laser bar which comprises at least two individual emitters. Here and in the following, a laser bar is understood to be a semiconductor component that can be handled separately and can be electrically contacted. A laser bar is produced in particular by separation from a wafer compound. A laser bar preferably comprises exactly one section of a semiconductor layer sequence grown in a wafer compound.

The individual emitters of the laser bar may be operated individually and independently of each other. For example, the laser bar comprises between two and nine individual emitters. Alternatively, the laser bar may comprise between ten and 500 individual emitters. The individual emitters of a laser bar may also be called laser diodes. The individual emitters are spaced apart regions of the laser bar where laser radiation is generated. For this purpose, each individual emitter comprises a partial region of the semiconductor layer sequence. The width of an individual emitter, measured parallel to a lateral transverse direction, is defined, for example, by the region of an active layer in which laser radiation is generated during the intended operation of the individual emitter. Here, the lateral transverse direction is a direction parallel to the main extension-plane of the active layer.

During intended operation of the laser bar, the individual emitters are, for example, simultaneously controlled and connected in parallel. Preferably, several individual emitters, in particular all individual emitters, generate laser radiation simultaneously during operation, which is coupled out of the laser bar along a radiation direction. For this purpose, the laser bar preferably comprises two facets opposite each other in the radiation direction, which form mirrors of a resonator. In particular, the electromagnetic radiation of different individual emitters is not necessarily coherent with one another.

For example, the width of each emitter is between 1 μm and 200 μm, preferably between 10 μm and 100 μm. In particular, the width of the emitters is measured along the lateral transverse direction at the facet of the individual emitters, through which electromagnetic radiation is coupled out during normal operation.

According to at least one embodiment, the light-emitting semiconductor component comprises a conversion element which is arranged downstream of the laser bar in a beam path. The conversion element is configured, for example, to convert the electromagnetic radiation emitted by the laser bar into electromagnetic radiation of another wavelength range. For example, the conversion element is formed with a conversion material which comprises, for example, phosphorus, titanium sapphire and/or garnets doped with rare earth metals, thiogallates, orthosilicates, aluminium oxynitrides, oxynitrides, aluminates, alkaline earth sulphides, alkaline earth silicon nitrides or combinations thereof. In particular, the conversion material may comprise a pressed powder, an epitaxially grown material and/or quantum dots. For example, the conversion element may comprise a carrier which may be formed with sapphire, glass and/or Plexiglas. The conversion element may comprise, for example, a matrix material, which may be crystalline, amorphous and/or polycrystalline. For example, the matrix material may be silicone, aluminium nitride or a glass. For example, the conversion element is formed in the form of a layer on a carrier. In normal operation, at least a majority of the electromagnetic radiation generated by the laser bar hits the conversion element.

According to at least one embodiment, at least some of the individual emitters are arranged next to each other in a lateral transverse direction. The lateral transverse direction runs, for example, perpendicular to the radiation direction, in which the laser bar emits a majority of the electromagnetic radiation during normal operation. For example, the individual emitters are arranged equidistantly to each other at least along the lateral transverse direction. In particular, the individual emitters can be arranged in pairs, so that the individual emitters can be arranged in pairs along the lateral transverse direction, in particular equidistant from one another.

According to at least one embodiment, the laser bar is formed with a nitride compound semiconductor material. A “nitride compound semiconductor material” means in the present context that a semiconductor layer sequence of the laser bar or at least a part thereof comprises or consists of a nitride compound semiconductor material, preferably AlₙGaₘIn₁₋ₙ₋ₘN, where 0≤n≤1, 0≤m≤1 and n+m≤1. In this context, this material does not necessarily have to have a mathematically exact composition according to the above formula. Rather, it may, for example, comprise one or more dopants and additional components. For simplicity's sake, however, the above formula only includes the essential components of the crystal lattice (Al, Ga, In, N), even if these may be partially replaced and/or supplemented by small amounts of other substances, for example to dope the material in a p- or n-conducting manner. In particular, the laser bar may be formed with aluminium gallium indium nitride (AlGaInN). Alternatively, the laser bar may also be formed with indium gallium aluminum phosphide (InGaAlP) and/or indium aluminum gallium arsenide (InAlGaAs). The semiconductor layer sequence comprises at least one p-type region, at least one n-type region and at least one active region. When the light-emitting component is operated as intended, electromagnetic radiation is generated in the active region. The semiconductor layer sequence of the laser bar is preferably continuos. An active layer of the laser bar can be continuous or segmented. The lateral extension of the laser bar, measured parallel to the main plane of extension of the active layer, is for example at most 1% or at most 5%, in particular at most 20%, greater than the lateral extension of the active layer.

According to at least one embodiment, the individual emitters are configured to emit primary radiation during intended operation. The primary radiation is a part of the electromagnetic radiation generated in the laser bar. For example, the primary radiation is in the green wavelength range, the blue wavelength range and/or the UV range. In particular, the primary radiation has a maximum bandwidth of 20 nm inclusive, in particular 10 nm inclusive. In particular, the individual emitters can each emit coherent radiation. The total laser radiation emitted by the individual emitters is the primary radiation.

According to at least one embodiment, the conversion element is configured to convert at least part of the primary radiation into secondary radiation, wherein the secondary radiation comprises a longer wavelength than the primary radiation. For example, the light-emitting semiconductor component may be configured to emit mixed light of primary radiation and secondary radiation. Alternatively, the light-emitting semiconductor component may be configured to emit secondary radiation only. For example, the electromagnetic radiation emitted by the light-emitting semiconductor component is white light.

According to at least one embodiment, the light-emitting semiconductor component comprises a laser bar, which comprises at least two individual emitters. Furthermore, the light-emitting semiconductor component comprises a conversion element which is arranged downstream of the laser bar in the beam path. At least some of the individual emitters are arranged side by side in the lateral transverse direction. The laser bar is formed with a nitride compound semiconductor material. The individual emitters are configured to emit primary radiation during normal operation and the conversion element is configured to convert at least part of the primary radiation into secondary radiation, the secondary radiation having a longer wavelength than the primary radiation.

A laser bar as it can be used in a light-emitting semiconductor component described here is described, for example, in the German patent application DE 102017119664.1, the disclosure content of which is hereby expressly included by reference.

A light-emitting semiconductor component described here is based on the following considerations, among others. To provide a compact light source, light emitting diodes (LED)-based light sources are used. However, the optical power density, which is determined by the luminous surface of the LEDs, is not sufficient for some applications. A higher optical power density is offered, for example, by individual laser diodes whose emitted primary radiation can be converted at least partially into electromagnetic radiation of a longer wavelength by means of a conversion element. However, the use of a plurality of individual laser diodes is limited due to their size, higher assembly costs and the greater effort required to adjust optical elements. Therefore, these solution approaches are associated with high manufacturing costs.

The light-emitting semiconductor component described here now makes use of the idea of providing a compact high-power light source with a laser bar in combination with a conversion element. Laser bars, for example, comprise a large number of individual emitters that are monolithically integrated, aligned and equidistant from one another. Due to the monolithic integration of the individual emitters, a particularly precise alignment of these is possible.

Furthermore, the monolithic integration of the individual emitters enables a particularly high power density of the emitted electromagnetic radiation.

Advantageously, the adjustment and mounting of optical elements such as lenses, prisms or the converter is simplified due to the exact positioning of the individual emitters relative to each other. This enables the production of a light-emitting semiconductor component with particularly high optical output powers and particularly high luminance at particularly low manufacturing costs. Furthermore, a light-emitting semiconductor component with a particularly high power density, improved beam quality and thus improved focusability of the emitted radiation is achieved.

According to at least one embodiment of the light-emitting component, the laser bar comprises an aluminum gallium indium nitride (AlGaInN)-based semiconductor layer sequence (1) with a contact side (10) and an active layer (11) for generating laser radiation. The contact side of the semiconductor layer sequence of the laser bar forms a cover surface or outer surface of the semiconductor layer sequence and may, for example, be formed with or consist of the material of the semiconductor layer sequence. The contact side preferably runs essentially parallel to the active layer.

The semiconductor layer sequence of the laser bar is grown or epitaxially deposited on a GaN growth substrate, for example. For example, the laser bar comprises the growth substrate. The growth substrate is arranged in particular on a side of the semiconductor layer sequence opposite the contact side. Between the active layer and the growth substrate, the semiconductor layer sequence is preferably n-type. Between the active layer and the contact side, the semiconductor layer sequence is preferably p-type. Between the active layer and the growth substrate, the semiconductor layer sequence preferably comprises one or more n-doped layers. Between the active layer and the contact side, the semiconductor layer sequence preferably comprises one or more p-doped layers.

The active layer may, for example, comprise a conventional pn junction, a double heterostructure, a single quantum well structure (SQW structure) or a multiple quantum well structure (MQW structure) for light generation. In particular, the semiconductor layer sequence may comprise several active layers arranged one above the other perpendicular to their main extension-plane. In addition to the active layer, the semiconductor layer sequence can comprise further functional layers and functional regions, such as p- or n-doped charge carrier transport layers, i.e. electron or hole transport layers, undoped or p- or n-doped confinement, cladding or waveguide layers, barrier layers, planarization layers, buffer layers, protective layers and/or electrodes as well as combinations thereof. In addition, additional layers, such as buffer layers, barrier layers and/or protective layers, may also be arranged perpendicular to the growth direction of the semiconductor layer sequence, for example around the semiconductor layer sequence, i.e. on the side surfaces of the semiconductor layer sequence.

According to at least one embodiment, the laser bar comprises several contact elements arranged next to each other in the lateral transverse direction and spaced apart from each other on the contact side. The contact elements serve for the electrical contacting of the individual emitters. The contact elements preferably do not join together, but are separate, electrically conductive structures on the contact side. Alternatively, the contact elements may be continuous. The individual emitters may be controlled by supplying the contact elements with current. Preferably, a contact element is assigned to each individual emitter, in particular assigned uniquely. In the unmounted state of the laser bar, the contact elements are preferably exposed or freely accessible.

In particular, the contact elements may each comprise or be formed from a metal, a metal alloy or mixture or a transparent conductive oxide such as indium tin oxide (ITO). For example, the contact elements have several layers of different contact materials. A first layer may, for example, comprise or consist of one or more materials selected from Pd, Pt, ITO, Ni and Rh. A second layer may, for example, comprise or consist of one or more materials selected from Pd, Pt, ITO, Ni, Rh, Ti, Pt, Au, Cr, (Ti)WN, Ag, Al, Zn, Sn and alloys thereof. A third layer or bond layer may, for example, comprise or consist of one or more materials selected from Ti, Pt, Au, Cr, (Ti)WN, Ag, Al and ITO, wherein the bond layer may also form the second layer depending on the choice of material. For example, the bond layer can also comprise a layer stack with several layers of different materials, for example a layer stack with layers of Ti, Pt and Au. For example, each contact element comprises a first layer and a second layer and a bond layer that are stacked on top of each other in this order. The first layer of the contact elements may be directly adjacent to the contact side.

The contact elements are preferably oblong or rod-shaped or strip-shaped. For example, the length of each contact element, measured along its longitudinal axis, is at least twice or at least 5 times or at least 10 times its width, measured perpendicular to the longitudinal axis. The widths of the contact elements are, for example, in the range between 1 μm and 200 μm inclusive. In particular, the elongated contact elements are arranged parallel to each other on the contact side. This means that the longitudinal axes of the contact elements are essentially parallel to each other. The longitudinal axes of the contact elements are preferably aligned along the radiation direction.

For example, two contact elements are at least 20 μm or at least 50 μm or at least 100 μm or at least 200 μm apart in the lateral transverse direction. Alternatively or additionally, the distance between each two adjacent contact elements is, for example, at most 1 mm or at most 600 μm or at most 400 μm.

According to at least one embodiment, each contact element is electrically conductively coupled to the semiconductor layer sequence via a continuous contact region on the contact side, so that a current flow between the semiconductor layer sequence and the contact element is made possible via the contact region. Each contact region of the contact side is thereby a continuous, preferably simply connected, region of the contact side and is thus formed from the semiconductor material of the semiconductor layer sequence. Each individual emitter preferably comprises exactly one contact region. However, it is also possible for each individual emitter to have at least two contact regions, for example parallel, which are, for example, at most 30 μm apart from each other. For example, each contact element completely covers the assigned contact region. The contact regions may be uniquely assigned to the contact elements. The contact elements may be in direct mechanical and electrical contact with the semiconductor layer sequence in the contact regions.

According to at least one embodiment, the laser bar comprises a thermal decoupling structure in the region between two adjacent individual emitters, which counteracts heat exchange between the two adjacent individual emitters. “In the region between two adjacent individual emitters” means in particular that the decoupling structure is arranged between two planes running through the adjacent individual emitters and perpendicular to the active layer. The thermal decoupling structure is arranged in particular in the lateral transverse direction between the two adjacent individual emitters. No further individual emitter is arranged between two adjacent individual emitters.

The thermal decoupling structure is preferably configured such that it reduces the thermal conductivity of the laser bar along the lateral transverse direction in the region between the two adjacent individual emitters. Alternatively or additionally, the thermal decoupling structure is configured to remove heat in the area between the two adjacent individual emitters.

According to at least one embodiment, the thermal decoupling structure comprises an electrically conductive cooling element applied to the contact side, which completely covers a continuous, preferably simply connected, cooling region of the contact side. The cooling region is a region of the contact side and is thus formed from the semiconductor material of the semiconductor layer sequence. The cooling region is formed in particular between the two contact regions of the two adjacent individual emitters.

The cooling element is preferably metallic. For example, the cooling element comprises or consists of one or more of the following materials: Au, Pd, Pt, ITO, Ni, Rh, Ti, Pt, Au, Cr, (Ti)WN, Ag, Al, Zn, Sn, In, W, Ta, Cu, AlN, SiC, DLC. In particular, the cooling element consists of the same material as the contact elements. In the unmounted state of the laser bar, the cooling element is preferably exposed, i.e. freely accessible.

According to at least one embodiment, the cooling element is electrically insulated from the semiconductor layer sequence along the cooling region. During normal operation, neither current is injected into the semiconductor layer sequence nor is current coupled out of the semiconductor layer sequence via the cooling region. “Electrically insulated” thus means in particular that in the cooling region the contact resistance between the cooling element and the semiconductor layer sequence is so great that no or no significant current flows over the cooling region when voltages are applied during specified normal operation.

Preferably, the cooling element is thermally coupled to the semiconductor layer sequence along the cooling region. For example, the space between the cooling element and the cooling region is filled with a material whose thermal conductivity is at least 1 W/(mK).

According to at least one embodiment, the cooling region has a width, measured along the lateral transverse direction, which is at least half as large or at least 1.5 times as large or at least twice as large or at least 3 times as large or at least 4 times as large as the width of each or at least one adjacent contact region. In particular, the area of the cooling region is at least half as large or at least 1.5 times as large or at least twice as large or at least 3 times as large or at least 4 times as large as the area of each or at least one adjacent contact region. The contact regions all have the same width and/or area within the manufacturing tolerance. An adjacent contact region is a contact region closest to the cooling region.

The cooling region may also be elongated, wherein the length is at least twice or at least 5 times or at least 10 times the width. The length of the cooling region may be between 80% and 120% of the individual lengths of the contact regions inclusive.

Furthermore, the decoupling structure may comprise a trench which extends at least partially through the laser bar in the vertical direction, perpendicular to the active layer, or perpendicular to the lateral transverse direction and perpendicular to the radiation direction. The width of the trench, measured parallel to the lateral transverse direction, is for example at least 5 μm or at least 10 μm or at least 50 μm. Alternatively or additionally, the width of the trench is for example at most 300 μm or at most 200 μm or at most 150 μm or at most 100 μm or at most 50 μm or at most 10 μm. For example, the length of the trench, measured parallel to the radiation direction, is at least twice the width or at least 5 times or at least 10 times the width of the trench. The depth of the trench is for example at least 100 nm or at least 500 nm or at least 1 μm, or at least 5 μm or at least 10 μm, or at least 50 μm or at least 100 μm.

The thermal decoupling structure may also include a cooling element with the associated cooling region and a trench.

So far, only a thermal decoupling structure have been discussed. Alternatively, the laser bar may comprise several thermal decoupling structures, for example between each pair of adjacent individual emitters. Each decoupling structure can also comprise two or more cooling elements, each of which completely covers a cooling region assigned to that cooling element. Each decoupling structure may also comprise a trench. Therefore, all specifications made here and in the following regarding a decoupling structure or a cooling element or a cooling region or a trench may apply accordingly to all decoupling structures and all cooling elements and all cooling regions and all trenches of the laser bar.

According to at least one embodiment, the maximum optical output power of the laser bar is at least 10 Watt. In particular, the maximum optical output power of the laser bar is at least 50 watts. The maximum optical output power of the laser bar is, for example, the optical output power with simultaneous operation of all individual emitters of the light-emitting semiconductor component. In particular, the maximum optical output power can be provided continuously for at least 100 hours, in particular at least 1000 hours, without damage to the laser bar. Advantageously, a particularly high optical output power can be achieved with the laser bar.

According to at least one embodiment, the primary radiation and/or secondary radiation is reflected in the conversion element. In particular, at least a large part of the secondary radiation leaves the conversion element through a side through which the primary radiation enters the conversion element. In particular, most of the secondary radiation leaving the conversion element has a different propagation direction than primary radiation hitting the conversion element. For example, most of the secondary radiation is emitted in the same direction from the conversion element. Advantageously, primary and/or secondary radiation is reflected in or at the conversion element, whereby the primary radiation travels a longer average path length within the conversion element. As a result, a particularly large proportion of the primary radiation is converted within the conversion element.

According to at least one embodiment, the primary radiation and/or secondary radiation is transmitted through the conversion element. For example, secondary radiation leaves the conversion element essentially along the propagation direction of the primary radiation hitting the conversion element. For example, at least a large part of the primary radiation and/or secondary radiation is emitted or transmitted along the radiation direction from the conversion element. In particular, at least a part of the primary and/or secondary radiation can be scattered in the conversion element or reflected or refracted at interfaces. It is advantageous that the heat input into the conversion element can be reduced by means of a conversion element through which the primary and/or secondary radiation is transmitted, since less primary radiation is converted into secondary radiation per unit volume within the conversion element.

According to at least one embodiment, the conversion element comprises a heat sink. In particular, the conversion material may be in direct mechanical contact with the heat sink. The heat sink is, for example, firmly connected to the conversion material either cohesively or frictionally. The heat sink, for example, is formed with a material that has a particularly high thermal conductivity. For example, the heat sink is formed with a metal, especially copper, aluminum nitride (AlN), copper tungsten (CuW), silicon carbide (SiC) or diamond. The heat sink is configured to dissipate heat generated in the conversion material during operation of the light-emitting semiconductor component. For example, the heat sink can be arranged on one side of the conversion material. The conversion material can be completely surrounded by the heat sink in a plane transverse to the radiation direction. In particular, the heat sink may have a recess through which a majority of the primary and/or secondary radiation strikes the conversion material and/or escapes from the conversion element during normal operation. The heat sink reduces the risk of damage to the conversion element due to excessive temperatures.

According to at least one embodiment, the conversion element comprises a reflector which is configured to reflect primary and/or secondary radiation. For example, the reflector is in direct mechanical contact with the conversion material. In addition, the reflector can be in direct mechanical contact with the heat sink. For example, the reflector is formed with a surface of the heat sink. In particular, the reflector can be formed with silver. Advantageously, a particularly high efficiency of the light-emitting semiconductor component is achieved by means of the reflector, since scattered primary and/or secondary radiation within the conversion element can be directed in the same direction by means of the reflector.

According to at least one embodiment, the conversion element comprises at least one concave or convex curved surface. For example, the conversion element is lens-shaped. In particular, the conversion element may be designed in the form of a biconcave, biconvex, concave-convex, plano-convex or plano-concave lens. The conversion element may also be cylindrical or conical. Advantageously, a concave or convex curved surface allows the electromagnetic radiation emerging from the conversion element to be influenced by refraction at the surface of the conversion element. Advantageously, the radiation characteristic of the light-emitting semiconductor component can be adjusted by means of the conversion element.

According to at least one embodiment, the light-emitting semiconductor component comprises a first optical element, in which the first optical element is arranged in the beam path of the primary radiation between the laser bar and the conversion element, and the intensity of the primary radiation can be varied by means of the optical element. The first optical element is a prism, for example, by means of which the direction in which the primary radiation propagates can be influenced. Alternatively, the first optical element may be a mirror which is configured to reflect the primary radiation. The mirror may have a curved surface so that the intensity of the electromagnetic radiation is changed by changing the cross-sectional area of the beam of primary radiation. In particular, the first optical element is configured to influence the cross-sectional area of the beam of primary radiation perpendicular to the propagation direction of the primary radiation. In particular, the intensity of the primary radiation can be varied by changing the cross-sectional area of the beam. For example, the optical element is formed with several lenses, mirrors, light guides, prisms, beam-combining optics, filters, diffractive elements and/or optical fibres. Advantageously, the intensity of the primary radiation incident on the conversion element is thus adjustable so that the heat input into the conversion element is distributed to a larger volume within the conversion element by converting primary radiation into secondary radiation. Advantageously, this reduces the risk of damage to the conversion element due to excessive heat input per unit volume.

According to at least one embodiment, the first optical element is configured to focus, expand and/or collimate the primary radiation in at least one direction perpendicular to the propagation direction of the primary radiation. For example, the first optical element is formed with a lens with which the primary radiation can be focused. Alternatively, the first optical element is configured to expand the primary radiation. In this context, expanding means that the cross-sectional area of the beam of primary radiation is increased along the propagation direction of the primary radiation. Furthermore, the optical element may be configured to collimate the primary radiation. In particular, the first optical element may be configured to collimate the primary radiation exactly in a spatial direction perpendicular to the propagation direction of the primary radiation. For example, the first optical element may be configured to collimate the primary radiation along a fast axis and/or along a slow axis of the laser bar. For example, the optical element is formed by two cylindrical lenses that are arranged rotated by 90° to each other for this purpose. Advantageously the primary radiation can be changed by means of the first optical element, so that the conversion element can be illuminated with a predetermined beam profile.

According to at least one embodiment, the first optical element comprises a light guide. The light guide, for example, is an optical fibre which is configured to guide primary radiation. In particular, the light guide may be configured to conduct particularly narrow-band electromagnetic radiation, such as primary radiation. Advantageously, an optical fiber allows the laser bar to be arranged independently of the location to be illuminated, so that the laser bar can be operated under optimized conditions. For example, the laser bar is thus protected from environmental influences, sunlight or moisture. In addition, a light guide can be used to provide currentless light sources for rooms in sensitive environments. In particular, maintenance work on the laser bar can be carried out without having to enter the area to be illuminated.

According to at least one embodiment, the first optical element comprises a beam-combining optics. For example, the beam-combining optics may be configured to combine the electromagnetic radiation, especially the primary radiation, of different individual emitters. In particular, the electromagnetic radiation of different individual emitters forms a beam with a greatly reduced diameter after leaving the first optical element. Advantageously, the primary radiation cannot be assigned to the individual emitters of the laser bar after passing through the first optical element, so that the primary radiation is perceived as mixed light after leaving the beam-combining optics.

According to at least one embodiment, the light-emitting semiconductor component comprises a second optical element, wherein the second optical element is arranged downstream of the conversion element in the beam path of the secondary radiation. In normal operation, at least a majority of the secondary radiation strikes the second optical element. For example, the second optical element may be a collimating or focusing lens for electromagnetic radiation emerging from the conversion element. In particular, the radiation characteristic of the light-emitting semiconductor component may be adjusted by means of the second optical element.

According to at least one embodiment, the second optical element comprises a filter, wherein the transparency of the filter is lower for primary radiation than for secondary radiation. In particular, the filter may be in direct mechanical contact with the conversion element. For example, the filter absorbs or reflects at least 70%, in particular at least 90%, of primary radiation. In particular, the filter reflects or absorbs a maximum of 10%, in particular a maximum of 5%, in particular a maximum of 1%, in particular a maximum of 0.1%, of the secondary radiation incident on the filter. Advantageously, the filter allows the color location of the electromagnetic radiation emitted by the light-emitting component to be adapted.

According to at least one embodiment, the individual emitters are arranged in a plurality lateral planes, wherein the lateral planes are parallel to the lateral transverse direction and parallel to the radiation direction of the individual emitters. In particular, several individual emitters can be arranged one above the other along a longitudinal direction. The longitudinal direction is perpendicular to the main extension plane of the laser bar. For example, individual emitters arranged one above the other in the longitudinal direction are electrically conductively connected to each other in a series circuit. Furthermore, individual emitters arranged next to each other along the lateral transverse direction can be electrically connected in parallel. Advantageously, such an arrangement of individual emitters enables a particularly compact design of the light-emitting semiconductor component, which has a particularly high optical output power. In addition, the primary radiation of the individual emitters can be shaped into a compact beam particularly easily by means of the first optical element, since the individual emitters are positioned particularly accurately relative to each other.

According to at least one embodiment, the light-emitting semiconductor component comprises a plurality of laser bars, wherein the laser bars are arranged one above the other perpendicularly to the lateral transverse direction and perpendicularly to the radiation direction. In particular, the light-emitting semiconductor component can comprise a plurality of laser bars which are arranged one above the other perpendicular to the radiation direction and perpendicular to the lateral transverse direction. In particular, the laser bars can be electrically conductively coupled to one another over their main surfaces. For example, the laser bars can be aligned relative to one another in such a way that the individual emitters emit electromagnetic radiation in the same direction. Advantageously, such a modular design of the light-emitting semiconductor component with a large number of laser bars makes it particularly easy to adjust the optical output power of the light-emitting semiconductor component.

Advantageous embodiments and developments of the light-emitting semiconductor component will become apparent from the exemplary embodiments described below in association with the figures.

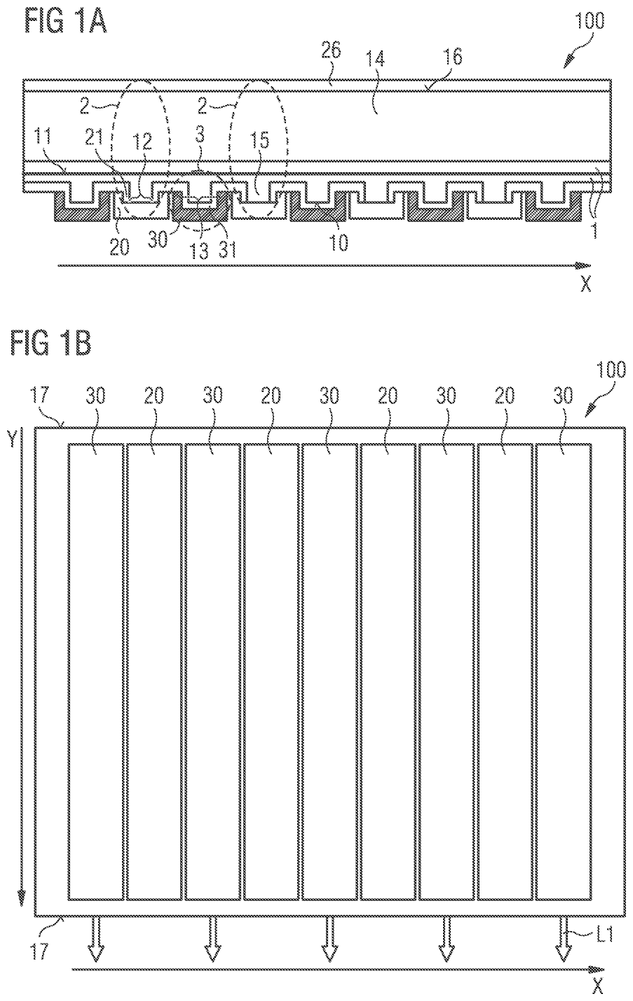

FIG. 1A shows a sectional view of a laser bar according to an exemplary embodiment of a light-emitting semiconductor component.

FIG. 1B shows a plan view of a contact side of a laser bar of a semiconductor light-emitting component according to an exemplary embodiment.

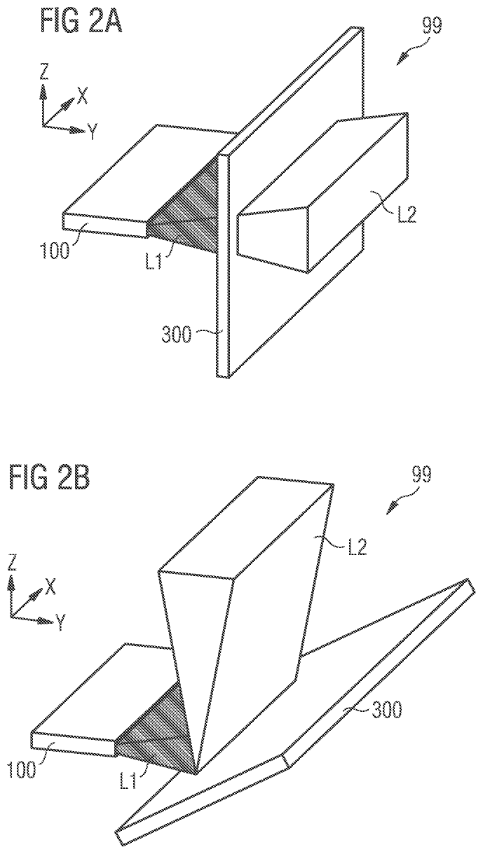

FIGS. 2A, 2B, 3A, 3B, 4A, 4B, 5A, 5B, 6A, 6B, 7A, 7B, 8A, 8B, 9A, 9B, 10A, 10B, 11A, 11B, 12A, 12B, 13A, 13B, 13C, 13D, 13E, 13F, 13G, and 13H show exemplary embodiments of semiconductor light-emitting components.

In the exemplary embodiments and figures, similar or similarly acting constituent parts are provided with the same reference symbols. The elements illustrated in the figures and their size relationships among one another should not be regarded as true to scale. Rather, individual elements may be represented with an exaggerated size for the sake of better representability and/or for the sake of better understanding.

FIG. 1A shows a cross-sectional view of the laser bar 100 of a light-emitting semiconductor component 99. The laser bar 100 comprises a semiconductor layer sequence 1 grown on a growth substrate 14. The semiconductor layer sequence 1 is based on AlInGaN. The growth substrate 14 is, for example, a GaN substrate. Semiconductor layer sequence 1 comprises an active layer 11, which has a pn junction or a quantum well structure, for example, and in which laser radiation is generated by recombination of charge carriers during normal operation.

The semiconductor layer sequence 1 comprises a contact side 10, which is formed by the semiconductor layer sequence 1. One side of the growth substrate 14 opposite the contact side 10 forms a counter contact side 16. Contact elements 20 are applied to the contact side 10. The contact elements 20 are arranged side by side and spaced apart from each other in a lateral transverse direction X, which runs parallel to the main extension plane of an active layer 11.

Each contact element 20 is electrically coupled to the semiconductor layer sequence 1 in a contact region 12, so that a current flow between the semiconductor layer sequence 1 and the contact element 20 is made possible via the contact region 12. A counter contact element 26 is arranged on the counter contact side 16.

By injecting charge carriers via the contact elements 20 and the contact element 26, charge carriers are injected into the semiconductor layer sequence 1, in particular into the active layer 11, during the intended operation of the laser bar 100, where they then recombine. Depending on via which of the contact elements 20 charge carriers are injected, a region of the active layer 11 arranged above the contact element 20 generates laser radiation. In this way, several individual emitters 2 or laser diodes 2 are defined. The ellipses with reference sign 2 each mark individual emitters 2. These individual emitters 2 are spaced apart and arranged next to each other in the lateral transverse direction X and generate and emit laser radiation during operation. The width of each individual emitter 2, measured along the lateral transverse direction X, is determined, for example, by the width of the region of the active layer 11 which generates laser radiation during operation of the individual emitter 2.

Each individual emitter 2 is formed as an index-guided laser diode in the exemplary embodiment of FIG. 1A. For this purpose, each individual emitter 2 comprises a rib 15 on the contact side 10, which is formed by the semiconductor layer sequence 1. The contact region 12 is formed on the side of the rib 15 facing away from the active layer 11. Side walls of the ribs 15, which extend perpendicular to the active layer 11, are covered with an electrically insulating layer 21. The contact elements 20 embrace the ribs 15 and are electrically connected to the semiconductor layer sequence 1 in the region of the contact regions 12. In the region of the side walls of the ribs 15, the contact elements 20 are electrically insulated from the semiconductor layer sequence 1 by the electrically insulating layer 21. The electrically insulating layer 21 comprises or consists, for example, of SiO2, silicon oxynitride, Si3N4, Al2O3, Ta2O5, TiO2 or ZrO2.

A decoupling structure 3 is provided in the region between two adjacent individual emitters 2, which counteracts a heat exchange between the two adjacent individual emitters 2 during the operation of laser bar 100. The decoupling structure 3 is marked with the dotted line with the reference sign 3.

In the exemplary embodiment of FIG. 1A, the decoupling structure 3 comprises a cooling element 30 which completely covers a cooling region 13 of the contact side 10. Along the cooling region 13, the cooling element 30 is electrically isolated from the semiconductor layer sequence 1 and thermally coupled to the semiconductor layer sequence 1. For this purpose, the cooling element 30 is spaced from the cooling region 13 by an isolation layer 31 and electrically insulated. In the example of FIG. 1A, the isolation layer 31 is formed by the electrically insulating layer 21, which extends over the cooling region 13.

The width of the cooling region 13, measured along the lateral transverse direction X, is greater than the width of the contact region 12, also measured along the lateral transverse direction X.

In FIG. 1A, the decoupling structure 3 also includes a rib 15 to which the cooling element 30 is attached and which embraces the cooling element 30.

In addition, each contact element 20 is equally spaced from the cooling element 30 on the left in the lateral transverse direction X and from the cooling element 30 on the right in the lateral transverse direction X. The contact elements 20 and the cooling elements 30 are arranged equidistant from each other.

The laser bar 100 of FIG. 1A may be soldered onto a heat sink. Both the contact elements 20 and the cooling element 30 can be soldered or glued to the heat sink using soldering material or adhesive. During operation of laser bar 100, the heat can then be efficiently dissipated from the semiconductor layer sequence 1 via cooling element 30 to the heat sink in the region between the two adjacent individual emitters 2.

As an alternative to the exemplary embodiment shown in FIG. 1A, the laser bar can be formed with gain-controlled laser diodes.

FIG. 1B shows the laser bar 100 of FIG. 1A in plan view of contact side 10. It can be seen that both the contact elements 20 and the cooling elements 30 are elongated or strip-shaped. The length of the contact elements 20 and the cooling elements 30 along their longitudinal axes is many times greater than their widths. The contact elements 20 and the cooling elements 30 are arranged at a distance from each other in the lateral transverse direction X, with the longitudinal axes of the cooling elements 20 and the contact elements 20 running parallel to each other. Furthermore, the contact elements 20 and the cooling elements 30 extend with their longitudinal axis along a radiation direction Y of the laser bar 100. In the radiation direction Y, primary radiation L1, which is generated in the individual emitters 2, is coupled out of the laser bar 100. For this purpose, the sides of the laser bar 100 opposite to each other in the radiation direction Y form facets 17. The facets 17 are at least partially reflective for the primary radiation L1. By means of the facets 17, for example, a resonator is formed.

For example, the laser bar has a length of between 200 μm inclusive and 11 mm along the lateral transverse direction. In particular, the laser bar can have a length along the lateral transverse direction of at most 50 mm inclusive or at most 11 mm inclusive or at most 5 mm inclusive. Preferably the laser bar has a length of 200 μm, 400 μm, 800 μm, 2 mm, 4.6 mm or 9.2 mm along the lateral transverse direction.

FIG. 2A shows a perspective schematic view of a light-emitting semiconductor component 99 according to an exemplary embodiment. The light-emitting semiconductor component 99 comprises a laser bar 100, which comprises at least two individual emitters 2. Furthermore, the light-emitting semiconductor component 99 comprises a conversion element 300, which is arranged downstream of the laser bar 100 in a beam path. In particular, the conversion element 300 is arranged downstream of laser bar 100 in radiation direction Y. The individual emitters 2 are arranged next to each other in the lateral transverse direction X. In particular, the individual emitters 2 are arranged next to each other in such a way that all individual emitters 2 emit primary radiation L1 along the radiation direction Y.

Laser bar 100 is formed with a nitride compound semiconductor material. For example, the laser bar 100 is configured to emit primary radiation L1 in the UV wavelength range, in the blue wavelength range and/or in the green wavelength range. The individual emitters 2 can be controlled separately. A conversion element 300 is arranged downstream of laser bar 100 in radiation direction Y. The conversion element 300 is configured to convert at least part of the primary radiation L1 into secondary radiation L2, wherein the secondary radiation L2 comprises a longer wavelength than the primary radiation L1. The primary radiation L1 can be partially transmitted by the conversion element 300. In particular, the secondary radiation L2 emerges from the conversion element 300 along the propagation direction of the primary radiation L1. In particular, a majority of the primary radiation L1 is converted into secondary radiation L2. For example, the maximum optical output power of laser bar 100 is at least 10 Watt, in particular at least 100 Watt.

FIG. 2B shows a schematic perspective view of a light-emitting semiconductor component 99 according to an exemplary embodiment. In contrast to the exemplary embodiment shown in FIG. 2A, the conversion element 300 is formed reflective. Thus the propagation direction of the secondary radiation L2 does not run along the propagation direction of the primary radiation L1, which strikes the conversion element 300. The primary radiation L1 and/or the secondary radiation L2 is reflected in the conversion element 300. For example, the conversion element 300 has a reflective layer, in particular a reflector, on a side facing away from laser bar 100, which is configured to reflect the primary radiation L1 and/or secondary radiation L2.

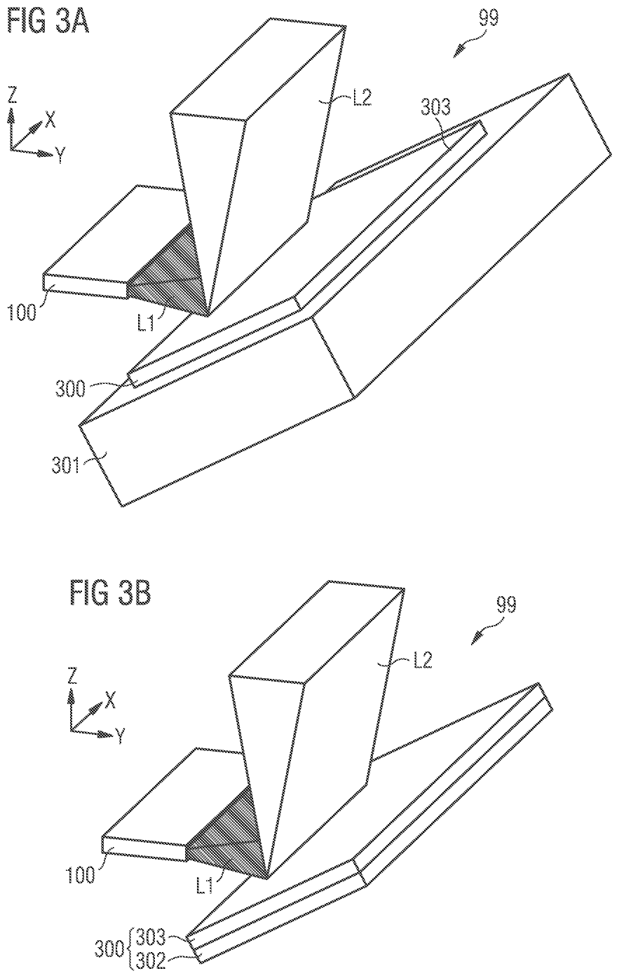

FIG. 3A shows a schematic perspective view of a light-emitting semiconductor component 99 according to an exemplary embodiment. In this example, the conversion element 300 comprises a heat sink 301, which is in direct mechanical contact with a conversion material 303 of the conversion element. In particular, the heat sink 301 is used to dissipate heat generated in the conversion material 303. The conversion material 303 may be formed, for example, by a phosphorus, titanium sapphire or rare earth metals, doped garnets, thiogallates, orthosilicates, aluminum oxynitrides, oxynitrides, aluminates, alkaline earth sulfides, alkaline earth silicon nitrides or combinations thereof. The heat sink 301, for example, is formed with a material that has a high thermal conductivity. For example, the heat sink 301 is formed with a metal, especially copper or copper-containing. Alternatively, the heat sink 301 may be formed with SiC, diamond, aluminum nitride and/or copper tungsten.

FIG. 3B shows a schematic perspective view of an exemplary embodiment of a light-emitting semiconductor component. In this example, the conversion element 300 is formed with a reflector 302 and conversion material 303. For example, the reflector 302 is formed with a metallic material which is configured to reflect primary radiation L1 and/or secondary radiation L2. In particular, the reflector 302 may be formed with silver. The reflector 302 is arranged on a side of the conversion material 303 facing away from laser bar 100. In particular, the use of a reflector 302 allows particularly efficient use of the conversion material 303, since the path length of the primary radiation L1 reflected by the reflector 302 is increased within conversion material 303. Thus a particularly large proportion of the primary radiation L1 is converted into secondary radiation L2. In particular, the conversion element can comprise a reflector 302 and a heat sink 301, with the reflector 302 being arranged between the heat sink 301 and the conversion material 303.

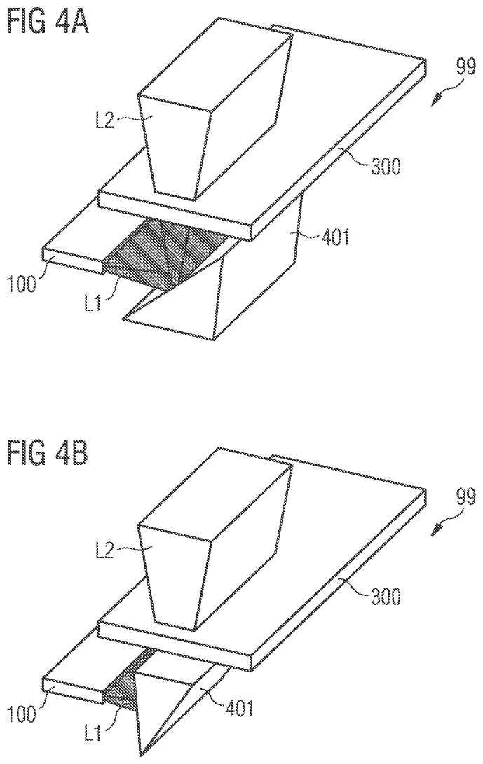

FIGS. 4A and 4B show schematic perspective views of light-emitting semiconductor components 99, which comprise a first optical element 401. In these exemplary embodiments, the first optical element 401 is a reflective prism. The reflection prism is configured to deflect primary radiation L1 with particularly low loss by means of total internal reflection on a surface of the prism. In particular, the first optical element 401 is configured to direct the primary radiation L1 to the conversion element 300.

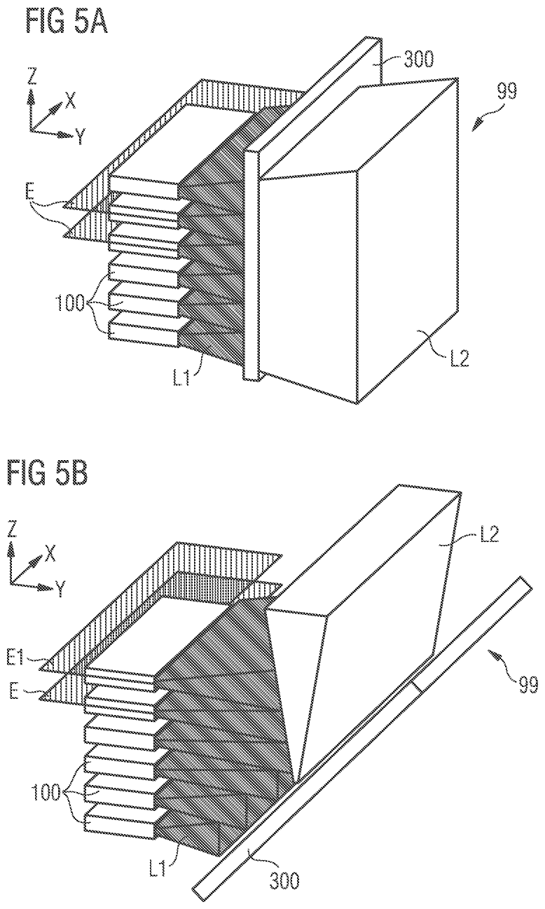

FIG. 5A shows a schematic perspective view of a light-emitting semiconductor component 99, which comprises a plurality of laser bars 100. The laser bars 100 are arranged on top of each other in several lateral planes E, each running along the lateral transverse direction X and the radiation direction Y. In particular, the laser bars 100 are electrically coupled to one another. For example, the laser bars 100 are connected in series. In particular, a laser bar 100 can comprise several individual emitters 2. For example, the individual emitters 2 can be arranged next to each other both along the lateral transverse direction X and along a longitudinal direction Z. In particular, individual emitters 2 which are arranged next to each other in a longitudinal direction can be assigned to a common laser bar 100. According to the exemplary embodiment shown in FIG. 5A, at least a majority of the electromagnetic radiation incident on the conversion element 300 is transmitted and converted. In particular, the secondary radiation L2 cannot be assigned to the individual laser bars 100 or the individual emitters 2.

In contrast to the exemplary embodiment shown in FIG. 5A, the conversion element 300 in FIG. 5B is reflective. Thus, the secondary radiation L2 has a different propagation direction than the primary radiation L1.

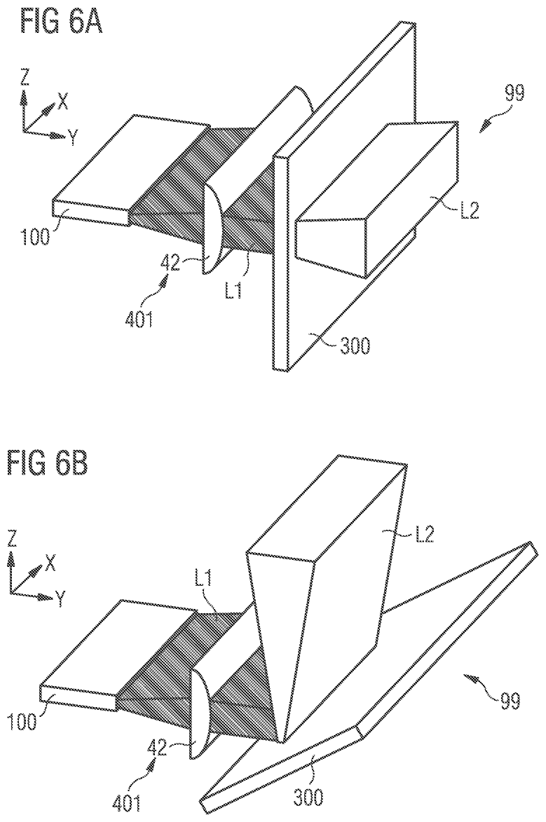

FIG. 6A shows a schematic perspective view of an exemplary embodiment of a light-emitting semiconductor component 99. In this example, a first optical element 401 is arranged downstream of laser bar 100. The first optical element 401 is arranged between the laser bar 100 and the conversion element 300 in radation direction Y. The first optical element 401 is formed with a cylindrical lens 42 which collimates the primary radiation L1 along the fast axis. In particular, the fast axis runs along the longitudinal direction Z. For example, the cylindrical lens 42 is configured to collimate the primary radiation L1 exclusively along the fast axis.

In contrast to the exemplary embodiment shown in FIG. 6A, in FIG. 6B the conversion element 300 is operated in reflection. In both the example shown in FIG. 6A and the example shown in FIG. 6B, the secondary radiation L2 is divergent.

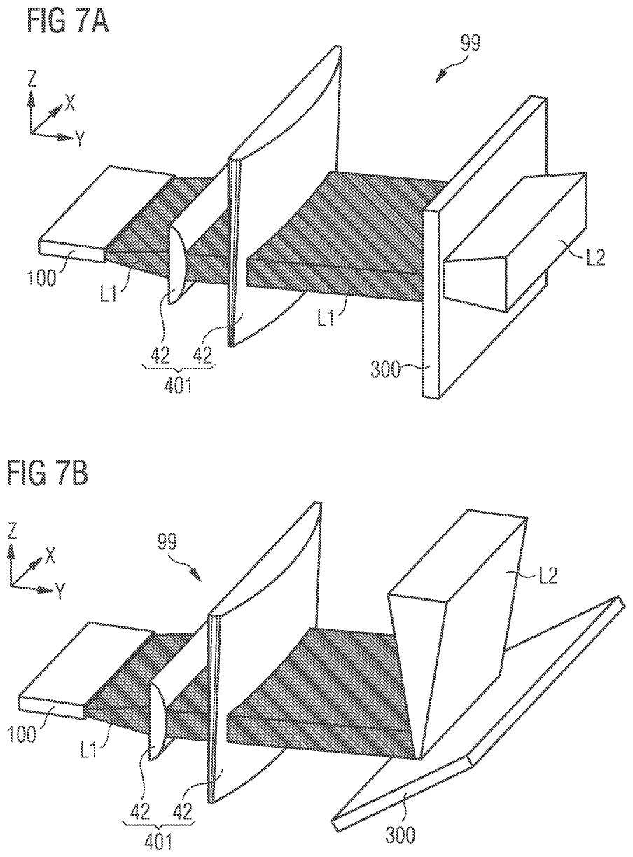

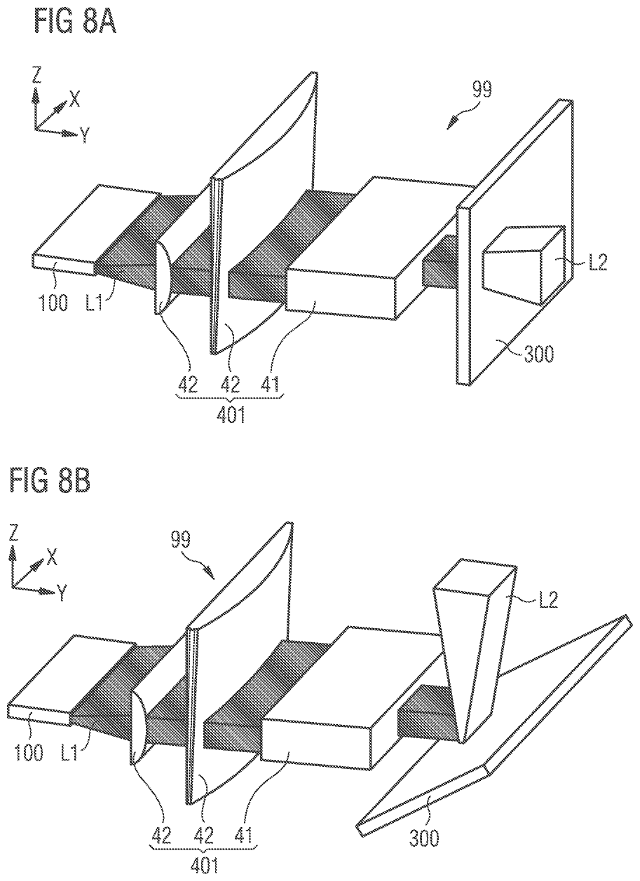

FIG. 7A shows a schematic perspective view of a light-emitting semiconductor component 99 according to an exemplary embodiment. The light-emitting semiconductor component 99 comprises a laser bar 100, which has a plurality of individual emitters 2. A first optical element 401 is arranged downstream of the laser bar 100 in radiation direction Y. Primary radiation L1 emitted by laser bar 100 passes through the first optical element 401. The first optical element 401 comprises two cylindrical lenses 42. The first cylindrical lens, which is first passed through by the primary radiation L1, is arranged to collimate the primary radiation L1 along the fast axis. In the present case, the fast axis is in the longitudinal direction Z. The second cylindrical lens 42, which is traversed second by the primary radiation L1, is arranged to collimate the primary radiation along the slow axis. In the present case the slow axis runs along the lateral transverse direction X. The primary radiation L1, which hits the conversion element 300, is collimated along the fast axis as well as along the slow axis. In the present case the conversion element 300 is used in transmission, so that the propagation directions the primary radiation L1 incident on the conversion element 300 and the secondary radiation L2 exiting the conversion element 300 are substantially the same. The secondary radiation L2 exiting the conversion element 300 is not necessarily coherent and is not collimated.

FIG. 7B shows a schematic perspective view of a light-emitting semiconductor component 99 according to an exemplary embodiment. Analogous to the exemplary embodiment shown in FIG. 7A, the semiconductor light-emitting component 99 comprises a laser bar 100, which is followed in radiation Y by a first optical element 401, which is arranged to collimate the primary radiation L1 emitted by the laser bar 100 along the fast axis and along the slow axis. In contrast to the exemplary embodiment shown in FIG. 7A, the conversion element 300 is operated in reflection, so that the secondary radiation L2 essentially has a different propagation direction than the primary radiation L1 which hits the conversion element 300. In particular, the secondary radiation L2 essentially emerges from a surface of the conversion element 300 which faces the first optical element 401 and/or the laser bar 100. For example, the primary radiation L1 hits the surface of the conversion element 300, through which the secondary radiation L2 emerges from the conversion element 300.

FIG. 8A shows a schematic perspective view of a light-emitting semiconductor component 99 according to an exemplary embodiment. Analogous to the exemplary embodiment shown in FIG. 7A, the semiconductor light-emitting component 99 comprises a laser bar 100, a first optical element 401 and a conversion element 300. The first optical element is located downstream of the laser bar 100 in the beam path of primary radiation L1. The first optical element 401 comprises two cylindrical lenses 42 which are arranged to collimate the primary radiation L1 along the fast axis and along the slow axis. The collimated primary radiation L1 then passes through a beam-combining optics 41, which is configured to superpose the primary radiation L1 of the different individual emitters 2. Thus, the beam-combining optics 41 emits primary radiation L1 which cannot be assigned to the individual emitters 2 of the laser bar 100. The primary radiation L1 then strikes the conversion element 300, which converts the primary radiation L1 into secondary radiation L2. The converted secondary radiation L2 is convergent, for example. In particular, the secondary radiation L2 may comprise parts of the primary radiation L1. For example, the secondary radiation L2 is mixed light from the primary radiation L1 and from primary radiation L1 converted in the conversion element 300.

FIG. 8B shows a perspective view of a light-emitting semiconductor component 99 according to an exemplary embodiment. In contrast to the exemplary embodiment shown in FIG. 8A, the conversion element is operated in reflection. Thus the surface of the conversion element 300 on which the primary radiation L1 impinges and from which the secondary radiation L2 emerges is the same. In particular, the side of the conversion element 300 facing the first optical element 101 and/or the laser bar 100 is inclined relative to the propagation direction of the primary radiation L1. Thus the primary radiation L1 and the secondary radiation L2 have different propagation directions. In particular, the propagation directions of the primary radiation L1 and the secondary radiation L2 are not antiparallel.

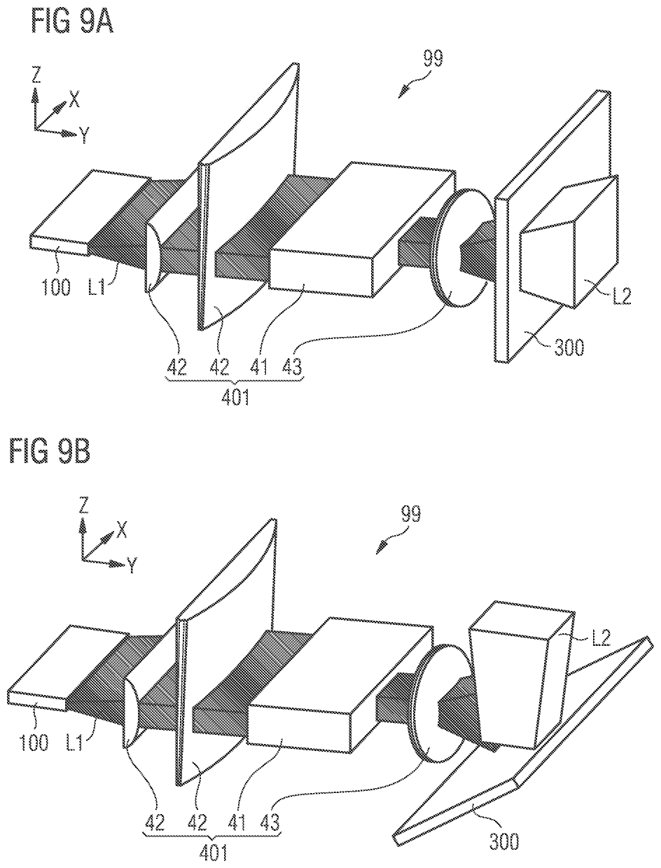

FIG. 9A shows a schematic perspective view of a light-emitting semiconductor component 99 with a laser bar 100, a first optical element 401 and a conversion element 300 of the exemplary embodiment. In contrast to the exemplary embodiment shown in FIG. 8A, the first optical element additionally comprises a lens 43, which is arranged downstream of the beam-combining optics 41 in the beam path of the primary radiation L1. The lens 43 is configured to expand the beam of the primary radiation and thus to change the intensity of the primary radiation L1. In particular, the expansion reduces the intensity of the primary radiation. It is advantageous that the intensity of the primary radiation L1, which strikes the conversion element 300, can be adjusted by means of the lens 43, so that, for example, the thermal load on the conversion element 300 is reduced. This prevents damage to the conversion element due to the temperature input caused by the conversion of primary radiation L1 into secondary radiation L2. In particular, the intensity of the primary radiation L1 can be reduced by means of the lens to such an extent that thermal quenching of the conversion element is avoided.

FIG. 9B shows a schematic perspective view of a light-emitting semiconductor component 99 according to an exemplary embodiment. In contrast to the example shown in FIG. 9A, the conversion element 300 is reflective.

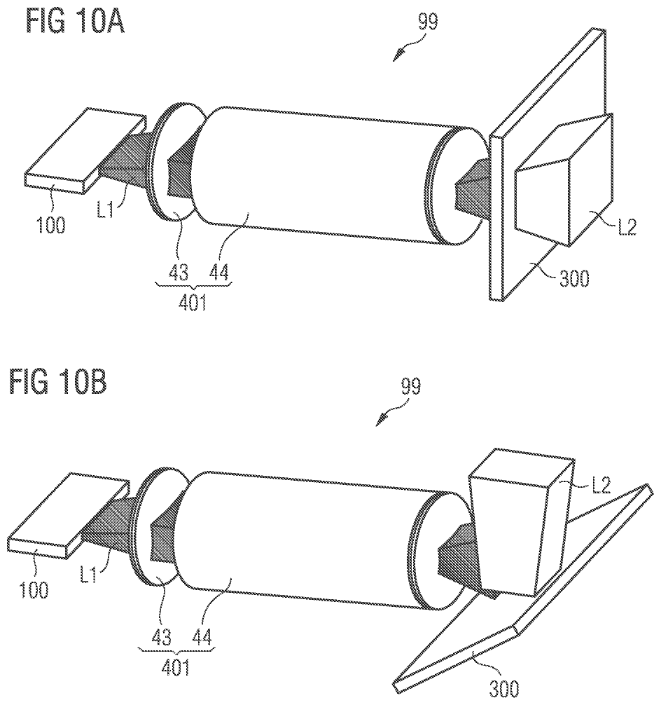

FIG. 10A shows a schematic perspective view of a light-emitting semiconductor component 99 according to an exemplary embodiment. The semiconductor light-emitting component 99 comprises a laser bar 100, a first optical element 401 and a conversion element 300. The first optical element 401 is formed with a lens 43 and with an optical fiber 44. The lens 43 is configured to focus the primary radiation L1. In particular, the lens 43 is configured to focus the primary radiation L1 in such a way that the primary radiation L1 can be coupled into the optical fiber 44. By means of the optical fiber 44, the primary radiation L1 is guided to a predeterminable location where the conversion element 300 is arranged. The primary radiation L1 coupled out of the optical fiber 44 is converted into secondary radiation L2 by means of the conversion element 300. The advantage of the optical fiber 44 is that the narrow-band primary radiation L1 can be guided particularly efficiently. Thus the losses until conversion at conversion element 300 are kept particularly low.

FIG. 10B shows a schematic perspective view of a light-emitting semiconductor component 99 according to an exemplary embodiment. In contrast to the exemplary embodiment shown in FIG. 10A, the conversion element 300 is operated in reflection.

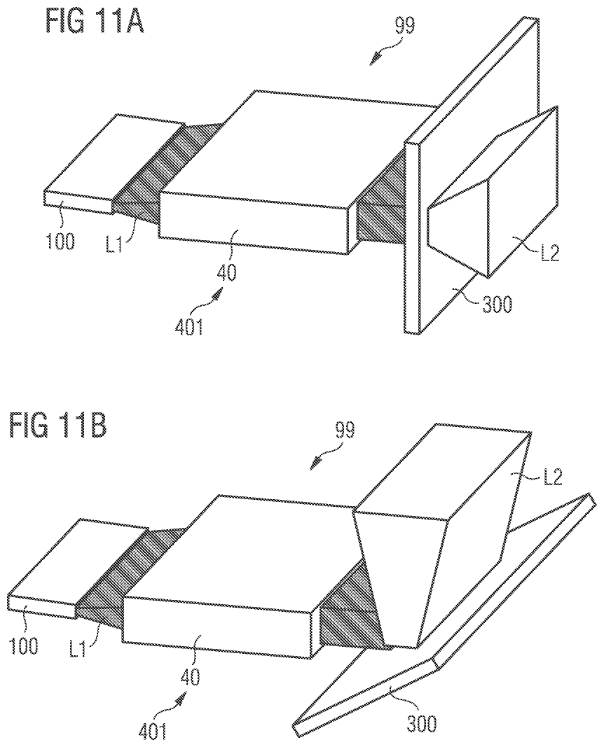

FIG. 11A shows a schematic view of a light-emitting semiconductor component 99 according to an exemplary embodiment. The light-emitting semiconductor component 99 comprises a laser bar 100, a first optical element 401 and a conversion element 300. The first optical element 401 is formed with a light guide 40. The primary radiation L1 emerging from the light guide 40 strikes the conversion element 300 and is converted into secondary radiation L2. In particular, the electromagnetic radiation is transmitted through conversion element 300. Accordingly, the primary radiation L1 enters the conversion element 300 through a surface of the conversion element 300 facing the first optical element 401 and/or the laser bar 100 and the secondary radiation L2 exits the conversion element 300 through a surface of the conversion element 300 facing away from the first optical element 401 and/or the laser bar 100.

In particular, this embodiment may be used, for example, as headlamp illumination of motor vehicles, rail vehicles or aircrafts. For example, the laser bar 100 cannot be arranged in a headlamp itself, but the light emitted by means of the laser bar is directed into the region of the beam-shaping optics of the headlamp by means of the light guide. Advantageously, this offers improved eye safety, since, for example, in the event of damage to the light guide 40, the laser bar 100 can be switched off using a fiber breakage detector. Furthermore, the use of a light guide 40 offers a special design freedom, since the headlamp only has to be adapted to the light guide and not to the light-generating component. Furthermore, such an embodiment can be particularly easy to maintain, since the laser bars 100 can be located in an easily accessible location, while the light guide 40 directs the emitted radiation to a location that may be difficult to reach. In addition, the use of a light guide 40 facilitates the cooling of the laser bar, since the laser bar can be arranged on a heat sink, for example, which has a particularly large heat capacity.

This enables a particularly safe and efficient illumination of large squares, road crossings, railway stations, airports, sports stadiums, sports and concert halls where the laser bar 100 producing primary radiation L1 is spatially separated from the area in which secondary radiation L2 is emitted.

FIG. 11B shows a schematic view of a light-emitting semiconductor component 99 according to an exemplary embodiment. In contrast to the exemplary embodiment shown in FIG. 11A, the conversion element 300 is not transmitting but reflecting.

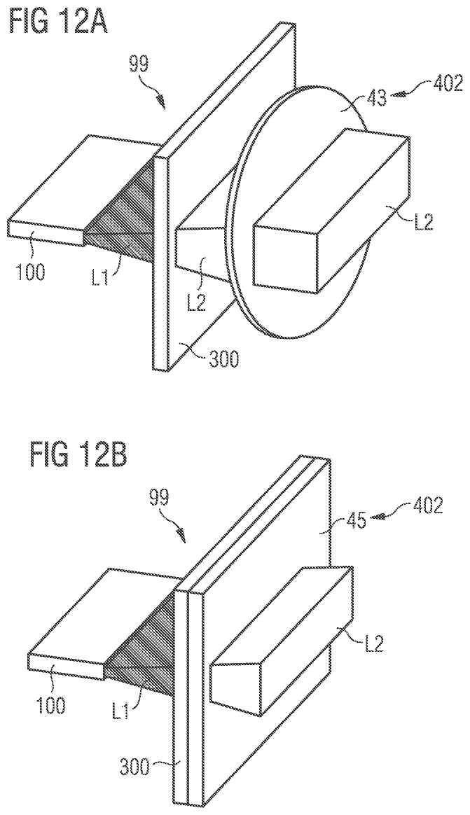

FIG. 12A shows a schematic view of a light-emitting semiconductor component 99 according to an exemplary embodiment. The light-emitting semiconductor component 99 comprises a laser bar 100, a conversion element 300 and a second optical element 402, the second optical element 402 being located downstream of the conversion element 300 in the beam path of the secondary radiation L2. In particular, the primary radiation L1, which is emitted by means of the laser bar 100, strikes the conversion element 300 directly without passing through further optical elements, in particular a first optical element. The second optical element 402 is formed with a lens 43 which is configured to influence the secondary radiation L2. For example, the lens 43 is configured to focus, scatter or collimate the secondary radiation L2.

FIG. 12B shows a schematic view of a light-emitting semiconductor component 99 according to an exemplary embodiment. The light-emitting semiconductor component 99 comprises a laser bar 100, a conversion element 300, and a second optical element 402. The second optical element is arranged downstream of the conversion element 300 in the beam path of the secondary radiation L2. In particular, the second optical element 402 is formed with a filter 45. For example, the filter 45 covers a surface of the conversion element 300, in particular completely. For example, filter 45 is configured to reflect or absorb primary radiation L1. Furthermore, the filter 45 may be configured to transmit secondary radiation L2. In particular, the filter 45 may be configured to transmit only a part of the electromagnetic radiation that leaves the conversion element 300. For example, the filter 45 may be in direct contact with the conversion element 300.

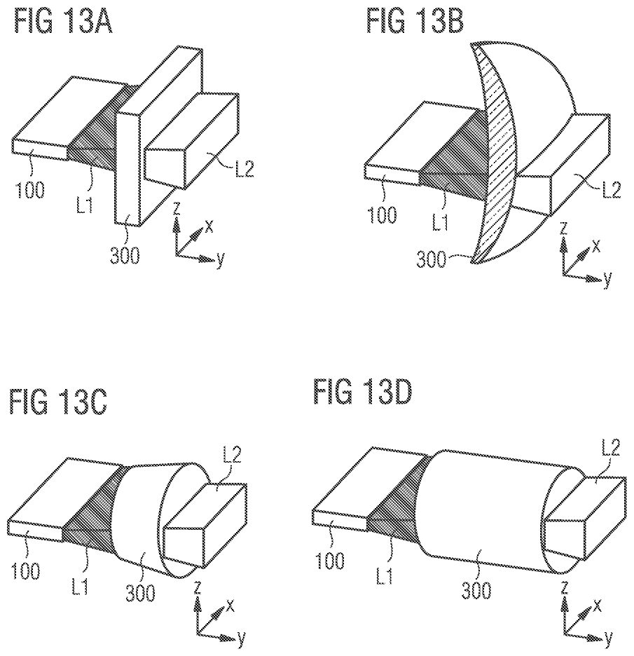

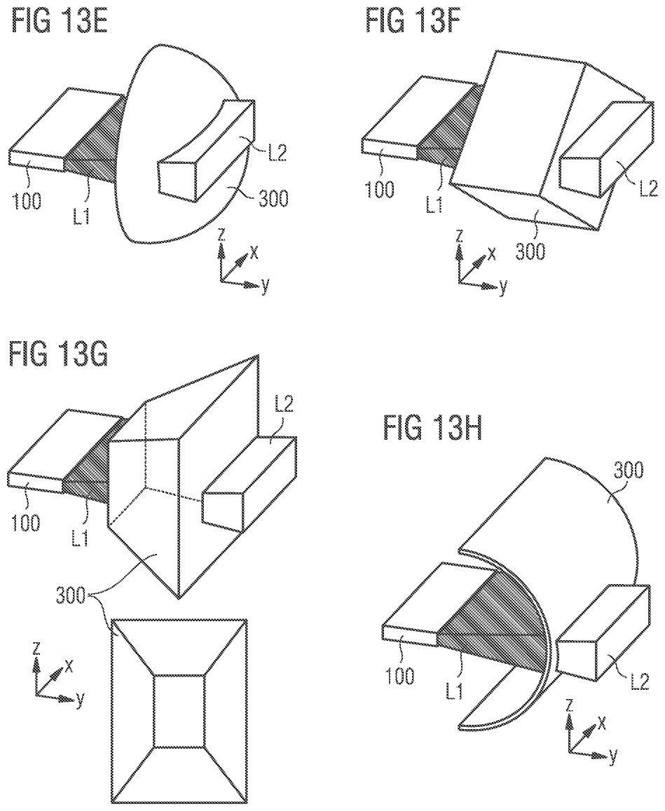

FIGS. 13A to 13H show schematic representations of different embodiments of light-emitting semiconductor components 99 formed with a laser bar 100 and a conversion element 300. Each conversion element 300 is configured to convert primary radiation L1 emitted by laser bar 100 into secondary radiation L2. As shown in FIG. 13A, the conversion element 300 may be formed as a cuboid, in particular as a layer. For example, the surfaces on which the primary radiation L1 impinges and from which the secondary radiation L2 emerges are flat. In particular, the opposing surfaces of the conversion element 300 run parallel to each other.

FIG. 13B shows an exemplary embodiment in which the conversion element 300 is shown in a sectional view. The surface of conversion element 300 facing the laser bar 100 is concave, for example. Furthermore, the surface of conversion element 300 facing away from laser bar 100 is convex. Thus the conversion element 300 has the additional effect of a concave-convex lens, so that the secondary radiation L2 can be focused, expanded or collimated with it.

FIG. 13C shows an exemplary embodiment in which the conversion element 300 is formed as a truncated cone. In particular, the conversion element 300 is rotationally symmetrical, so that, for example, the conversion element 300 can be rotated during operation of laser bar 100. In particular, the area of the conversion element 300, which is irradiated with primary radiation L1, can be changed by means of the rotation in order to reduce the thermal load on the conversion element 300.

FIG. 13D shows an alternative exemplary embodiment in which the conversion element 300 is cylindrical. The primary radiation L1 hits a flat surface of the conversion element.

The converted electromagnetic radiation emerges from the conversion element 300 as secondary radiation L2 through an opposite flat surface of the cylindrical conversion element 300. Alternatively, the conversion element 300 may be configured to be illuminated with primary radiation L1 on its curved outer surface.

FIG. 13E shows an exemplary embodiment in which the conversion element 300 is lens-shaped. In particular, the conversion element 300 is formed as a plan-convex lens. For example, the secondary radiation L2 is refracted at the surface of the conversion element 300 so that the secondary radiation L2 can be focused, collimated or expanded by means of the conversion element 300.

FIG. 13F shows an exemplary embodiment in which the conversion element 300 has the form of a cuboid.

FIG. 13G shows an exemplary embodiment in which a sectional view of conversion element 300 and a plan view of the side of conversion element 300 facing the laser bar 100 are shown. The conversion element 300 is formed as a truncated pyramid. The conversion element 300 is configured that the primary radiation L1 enters the conversion element 300 through the smaller rectangular surface. The secondary radiation L2 exits through the opposite larger rectangular surface of the conversion element. In particular, the trapezoidal side surfaces of the conversion element 300 can be reflective in order to couple out secondary radiation L2 from the conversion element 300 on the side facing away from the laser bar 100 with particular efficiency.

FIG. 13H shows an exemplary embodiment in which the conversion element 300 is form as a thin curved body. For example, the conversion element 300 is designed as a foil, which can be bent, for example. By bending the conversion element 300, the radiation profile of the secondary radiation L2 may be adapted.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

This patent application claims the priority of German patent application 102017121480.1, the disclosure content of which is hereby incorporated by reference.

### REFERENCE NUMERALS

1 semiconductor layer sequence
2 individual emitter
3 thermal decoupling structure
10 contact side of the semiconductor layer sequence 1
11 active layer
12 contact region of the contact side 10
13 cooling region of the contact side 10
14 growth substrate
15 rib
16 counter contact side
17 facet
20 contact element
21 electrically insulating layer
23 contact layer
26 counter contact element
30 cooling element
31 isolation layer
35 trench
40 light guide
41 beam-combining optic
42 cylindrical lens
43 lens
44 optical fibre
45 filter
99 light-emitting semiconductor component
100 laser bar
200 connection board
300 conversion element
300a surface of the conversion element
301 heat sink
302 reflector
303 conversion material
401 first optical element
402 second optical element
E1 first lateral plane
E lateral plane
L1 primary radiation
L2 secondary radiation
X lateral transverse direction
Y radiation direction
Z longitudinal direction

1. A light-emitting semiconductor component with a laser bar, which comprises at least two individual emitters, and a conversion element, which is arranged downstream of the laser bar in a beam path, in which
at least some of the individual emitters are arranged side by side in a lateral transverse direction,
the laser bar is formed with a nitride compound semiconductor material,
the individual emitters are configured to emit primary radiation during intended operation and
the conversion element is configured to convert at least part of the primary radiation into secondary radiation, wherein the secondary radiation comprises a longer wavelength than the primary radiation.

2. The light-emitting semiconductor component according to claim 1, wherein the laser bar:
comprises an AlGaInN-based semiconductor layer sequence with a contact side and an active layer for generating laser radiation,
comprises a plurality of contact elements arranged next to one another and spaced apart from one another in the lateral transverse direction on the contact side for electrically contacting the individual emitters, wherein
each contact element is assigned to an individual emitter,
each contact element is electrically conductively coupled to the semiconductor layer sequence via a continuous contact region of the contact side, so that a current flow between the semiconductor layer sequence and the contact element is enabled via the contact region,
the laser bar comprises a thermal decoupling structure in the region between two adjacent individual emitters, which counteracts a heat exchange between the two adjacent individual emitters,
the decoupling structure comprises an electrically conductive cooling element which is applied to the contact side and completely covers a continuous cooling region of the contact side,
the cooling element is electrically insulated from the semiconductor layer sequence along the cooling region and is thermally coupled to the semiconductor layer sequence along the cooling region, and
the cooling region has a width, measured along the lateral transverse direction, which is at least half the width of an adjacent contact region.

3. The light-emitting semiconductor component according to claim 1, wherein the maximum optical output power of the laser bar is at least 10 Watt.

4. The light-emitting semiconductor component according to claim 1, in which the primary radiation and/or secondary radiation is reflected in the conversion element.

5. The light-emitting semiconductor component according to claim 1, wherein primary radiation and/or secondary radiation is transmitted through the conversion element.

6. The light emitting semiconductor component according to claim 1, wherein the conversion element comprises a heat sink.

7. The light-emitting semiconductor component according to claim 1, in which the conversion element comprises a reflector which is configured to reflect primary radiation and/or secondary radiation.

8. The light-emitting semiconductor component according to claim 1, wherein the conversion element comprises at least one concave or convex curved surface.

9. The light-emitting semiconductor component according to claim 1, with a first optical element, in which the first optical element is arranged in a beam path of the primary radiation between the laser bar and the conversion element, and
the intensity of the primary radiation is variable by means of the first optical element.

10. The light-emitting semiconductor component according to claim 1, wherein
the first optical element focuses, expands and/or collimates the primary radiation in at least one direction perpendicular to the propagation direction of the primary radiation

11. The light-emitting semiconductor component according to claim 1, wherein the first optical element comprises a light guide.

12. The light-emitting semiconductor component according to claim 1, wherein the first optical element comprises a beam-combining optic.

13. The light-emitting semiconductor component according to claim 1, with a second optical element, in which the second optical element is arranged downstream of the conversion element in the beam path of the secondary radiation.

14. The light-emitting semiconductor component according to claim 1, in which the second optical element comprises a filter, wherein the transparency of the filter is lower for primary radiation than for secondary radiation.

15. The light-emitting semiconductor component according to claim 1, wherein the individual emitters are arranged in a plurality of lateral planes, wherein the lateral planes are parallel to the lateral transverse direction and parallel to a radiation direction.

16. The light-emitting semiconductor component according to claim 1, comprising a plurality of laser bars, wherein the laser bars are arranged one above the other perpendicular to the lateral transverse direction and perpendicular to a radiation direction.

17. A light-emitting semiconductor component with a laser bar, which comprises at least two individual emitters, and a conversion element, which is arranged downstream of the laser bar in a beam path, in which
at least some of the individual emitters are arranged side by side in a lateral transverse direction,
the laser bar is formed with a nitride compound semiconductor material,
the individual emitters are configured to emit primary radiation during intended operation,
the conversion element is configured to convert at least part of the primary radiation into secondary radiation, wherein the secondary radiation comprises a longer wavelength than the primary radiation, and
primary radiation and/or secondary radiation is transmitted through the conversion element.

18. A light-emitting semiconductor component with a laser bar, which comprises at least two individual emitters, and a conversion element, which is arranged downstream of the laser bar in a beam path, in which
at least some of the individual emitters are arranged side by side in a lateral transverse direction,
the laser bar is formed with a nitride compound semiconductor material,
the individual emitters are configured to emit primary radiation during intended operation,
the conversion element is configured to convert at least part of the primary radiation into secondary radiation, wherein the secondary radiation comprises a longer wavelength than the primary radiation, and
the individual emitters are arranged in a plurality of lateral planes, wherein the lateral planes are parallel to the lateral transverse direction and parallel to a radiation direction.
